(19) United States
(12) Patent Application Publication
(10) Pub. No.: US 2013/0194751 A1
(43) Pub. Date: Aug. 1, 2013

(54) CONTROLLING HEAT TRANSFER USING AIRFLOW-INDUCED FLUTTER OF CANTILEVERED ELASTIC PLATES

(71) Applicants: Wei Ling, Randolph, NJ (US); Salvatore J. Messana, Morris Plains, NJ (US); Paul M. Rominski, Morris Plains, NJ (US)

(72) Inventors: Wei Ling, Randolph, NJ (US); Salvatore J. Messana, Morris Plains, NJ (US); Paul M. Rominski, Morris Plains, NJ (US)

(21) Appl. No.: 13/360,939

(22) Filed: Jan. 30, 2012

(51) Int. Cl. H05K 7/20; F28F 27/00

(52) U.S. Cl. 361/707; 165/200

(57) ABSTRACT

A capability for controlling heat transfer using airflow-induced fluttering of a cantilevered elastic plate is presented. A mounting structure is configured to be coupled to a surface of an element having a heat generating component coupled thereto. An elastic place is coupled to the mounting structure so as to arrange the elastic plate in a cantilevered position with respect to the surface of the element and at a position above the surface of the element when the mounting structure is coupled to the surface of the element. The elastic plate is configured to flutter, in response to air flow incident on the elastic plate, in a manner tending to disrupt the boundary layer region. The elastic plate may be arranged at a position that is selected based on a determined location of the boundary layer region.

### TECHNICAL FIELD

This case relates generally to cooling of components and, more specifically but not exclusively, to cooling of electronic components on printed circuit board assemblies.

### BACKGROUND

There are many types of equipment and devices that include heat generating components (e.g., telecommunications equipment as well as various other types of heat generating devices). In many cases, it may be necessary or desirable to at least partially cool such heat generating components and/or areas near the heat generating components. Some typical cooling schemes include use of heat sinks on heat generating components and use of fans to produce airflow. In many cases, however, such cooling schemes are not adequate to produce the necessary or desired amount of cooling.

### SUMMARY

Various deficiencies in the prior art are addressed by embodiments for improving cooling of components and devices.

In one embodiment, an apparatus includes an element having a surface, a heat generating component coupled to the surface of the element, a mounting structure coupled to the surface of the element, and an elastic plate coupled to the mounting structure. The elastic plate is coupled to the mounting structure so as to arrange the elastic plate in a cantilevered position with respect to the surface of the element and at a position above the surface of the element. The elastic plate is configured to flutter, in response to air flow incident on the elastic plate, in a manner tending to disrupt a boundary layer region.

In one embodiment, an apparatus includes a printed circuit board having a surface, a heat generating component coupled to the surface of the printed circuit board, a mounting structure coupled to the surface of the printed circuit board, and an elastic plate coupled to the mounting structure. The elastic plate is coupled to the mounting structure so as to arrange the elastic plate in a cantilevered position with respect to the surface of the element and above the surface of the element. The elastic plate is configured to flutter, in response to air flow incident on the elastic plate, in a manner tending to disrupt a boundary layer region.

In one embodiment, an apparatus includes a mounting structure and an elastic place coupled to the mounting structure. The mounting structure is configured to be coupled to a surface of an element having a heat generating component coupled thereto. The elastic place is coupled to the mounting structure so as to arrange the elastic plate in a cantilevered position with respect to the surface of the element and above the surface of the element when the mounting structure is coupled to the surface of the element. The elastic plate is configured to flutter, in response to air flow incident on the elastic plate, in a manner tending to disrupt a boundary layer region.

### BRIEF DESCRIPTION OF THE DRAWINGS

The teachings herein can be readily understood by considering the following detailed description in conjunction with the accompanying drawings, in which:

FIG. 1 depicts a side view of an exemplary printed circuit board assembly illustrating a thermal/viscous boundary layer region that forms proximate the printed circuit board assembly during operation of the printed circuit board assembly;

FIG. 2 depicts a side view of the exemplary printed circuit board assembly of FIG. 1 illustrating use of an elastic plate to disrupt the thermal/viscous boundary layer region formed proximate the printed circuit board of FIG. 1;

FIG. 3 depicts a view of an exemplary elastic plate configured for use as the elastic plate of FIG. 2;

FIGS. 4A and 4B depict views of an exemplary mounting structure configured to mount the elastic plate of FIG. 3 to the printed circuit board of FIG. 1;

FIGS. 5A and 5B depict side and top views of an exemplary printed circuit board assembly illustrating use of the mounting structure of FIG. 4 to mount the elastic plate of FIG. 2 such that the elastic plate is cantilevered with respect to the printed circuit board of FIG. 1;

FIG. 6 depicts a side view of the exemplary printed circuit board assembly of FIG. 5 illustrating use of heat sinks on the heat generating components of the printed circuit board assembly of FIG. 5; and

FIG. 7 depicts a side view of an exemplary printed circuit board assembly illustrating mounting of multiple elastic plates to a printed circuit board such that the multiple elastic plates are aligned parallel to the direction of air flow.

To facilitate understanding, identical reference numerals have been used, where possible, to designate identical elements that are common to the figures.

### DETAILED DESCRIPTION

A cooling capability, for improving cooling of heat generating components, is depicted and described herein, although various other capabilities also may be presented herein. The cooling capability may be used to improve cooling of various types of components on various types of elements, such as electronic heat generating components such as may be found on electronic devices (e.g., heat generating components on printed circuit boards, heat sinks associated with heat generating components on printed circuit boards, and the like), mechanical heat generating components such as may be found on mechanical devices, and the like, as well as various combinations thereof.

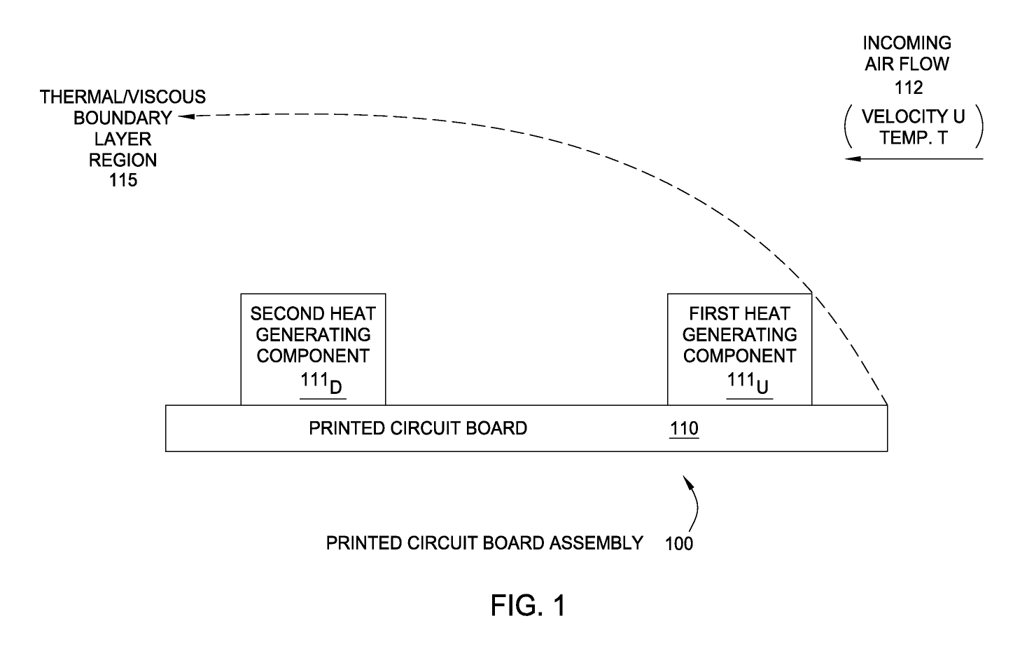

FIG. 1 depicts a side view of an exemplary printed circuit board assembly illustrating a thermal/viscous boundary layer region that forms proximate the printed circuit board assembly during operation of the printed circuit board assembly.

The printed circuit board assembly (PCBA) 100 includes a printed circuit board (PCB) 110 and a pair of heat generating components 111 including a first heat generating component 110_{U} and a second heat generating component 111_{D}. The heat generating components 111 are coupled to a surface of the PCB 110. It will be appreciated that the PCB 110 is likely to include many other components, including both those that generate heat and those that do not generate heat, which components have been omitted for purposes of clarity. The various types of printed circuit board assemblies (including the numbers, types, and arrangements of components which can be disposed thereon) will be understood by one skilled in the art.

As depicted in FIG. 1, an incoming air flow is incident on PCBA 100. The incoming air flow 112 has a velocity U and a temperature T. The incoming airflow 112 is indicated as flowing in a direction from the first heat generating component 110_{U} toward the second heat generating component 111_{D}, such that the first heat generating component 111_{U} also may be referred to herein as an upstream heat generating component and the second heat generating component 111_{D} also may be referred to herein as a downstream heat generating component).

As further depicted in FIG. 1, at least one boundary layer region may form proximate the PCBA during operation of PCBA 100. More specifically, the at least one boundary layer region tends to form near the PCB 110 and, more specifically, near the surface of PCB 110 on which the heat generating components 111 are disposed. It will be appreciated that two distinct boundary layer regions tend to develop when air flows over a stationary heated surface such as the surface of first heat generating component 111_{U} of PCBA 100: (1) a thermal boundary layer region (due to the temperature difference between the surface and the temperature of the incoming air flow 112) and (2) a viscous boundary layer region (e.g., due to the difference in velocity at the surface due to viscous drag (i.e., zero velocity or no-slip condition at the surface) and the incoming free stream air flow velocity of the incoming air flow 112). Accordingly, in FIG, 1, the at least one boundary layer region is represented using a line labeled as thermal/viscous boundary layer region 115. In general, the thermal and viscous boundary layer regions have different heights or thicknesses (e.g., which may be measured as the distance from the stationary surface to the location in the air stream where the air flow temperature or velocity is at or approximately 99% of the free stream value, or in any other suitable manner). Thus, the line in FIG. 1 that is labeled thermal/viscous boundary layer region 115 is intended as a representative (symbolic) demarcation between the boundary layer (thermal or viscous) region (where either temperature or velocity is different/less than the free stream value) and the free stream region. In other words, the boundary layer region is not the line that is depicted; rather it is the region between the stationary surface and the symbolic demarcation line. It also will be appreciated that the specific thickness of each boundary layer region may be dependent on the Prandtl and Reynolds number for the specific flow and thermal conditions and, further, that depending on these characteristic dimensionless numbers the thermal boundary layer thickness may be greater than or less than the viscous boundary layer thickness. It also will be appreciated that the thermal boundary region develops if the surface is a different temperature (e.g., heated) than the temperature of the incoming air flow 112, so the thermal boundary region typically develops at a location father downstream than the viscous boundary region since the first heat generating component 111_{U} typically is not located at the leading edge of the PCB 110. Thus, from the foregoing, it will be appreciated that the at least one boundary layer region may include one or more of a thermal boundary layer region, a viscous boundary layer region, and the like, as well as various combinations thereof.

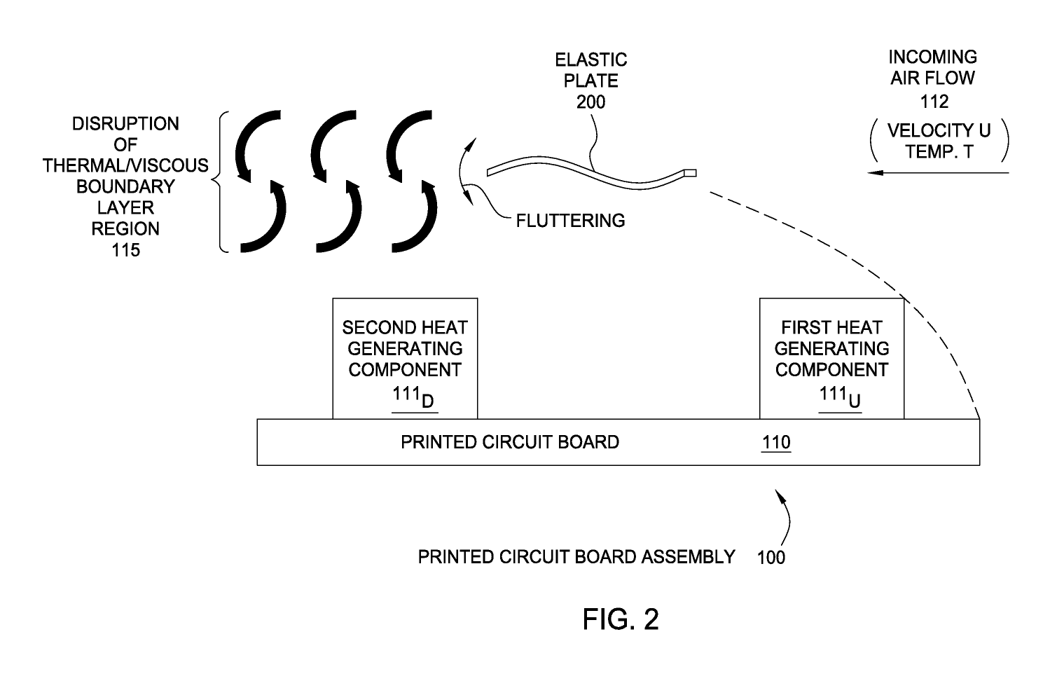

In one embodiment, the thermal/viscous boundary layer region 115 that forms proximate PCB 110 may be at least partially disrupted via use of one or more elastic plates configured to be cantilevered with respect to the surface PCB 110 and at a position above the surface PCB 110 and further configured to flutter in response to an air flow incident thereon. Various embodiments illustrating use of one or more cantilevered elastic plates to disrupt the thermal/viscous boundary layer region 115 which forms proximate PCB 110 are depicted and described with respect to FIGS. 2-7.

FIG. 2 depicts a side view of the exemplary printed circuit board assembly of FIG. 1 illustrating use of an elastic plate to disrupt the thermal/viscous boundary layer region formed proximate the printed circuit board assembly of FIG. 1.

As depicted in FIG. 2, the configuration of PCBA 100 is similar to that depicted and described with respect to FIG. 1 (illustratively, air flow 112, in combination with heat generated by heat generating components 111, results in formation of the thermal/viscous boundary layer region 115).

As further depicted in FIG. 2, an elastic plate 200 is arranged at a position above the surface of the PCBA 100.

In one embodiment, the elastic plate 200 is arranged at a position above the surface of the PCBA 100 where the position of elastic plate 200 is independent of the location of thermal/viscous boundary layer region 115. The arrangement of elastic plate 200 at a position above the surface of the PCBA 100 provides at least some disruption of the thermal/viscous boundary layer region 115 when the elastic plate 200 flutters in response to air flow 112 being incident on elastic plate 200, even where the position of elastic plate 200 is selected independent of the location of thermal/viscous boundary layer region 115. In other words, even where the elastic plate 200 is mounted at a position above the surface of the PCBA 100 without regard to the location of thermal/viscous boundary layer region 115, at least some level of benefit is realized when the elastic plate 200 flutters in response to air flow 112 being incident on elastic plate 200 (e.g., there is at least some disruption of thermal/viscous boundary layer region 115 sufficient to provide at least some cooling near PCB 110). This is depicted in FIG. 2, where the elastic plate 200 is positioned above the surface of PCBA 100.

In one embodiment, the elastic plate 200 is arranged at a position above the surface of the PCBA 100 where the position of elastic plate 200 is selected based on the location of thermal/viscous boundary layer region 115. This is expected to provide improved (or even optimized) disruption of the thermal/viscous boundary layer region 115 by the fluttering of elastic plate 200 when compared with the case in which the position of elastic plate 200 is selected independent of the location of thermal/viscous boundary layer region 115. This is depicted in FIG. 2, where the elastic plate 200 is arranged at a position that is determined to be proximate the thermal/viscous boundary layer region 115. It is noted that arrangement of elastic plate 200 at a position determined to be proximate the location of the thermal/viscous boundary layer region 115 indicates arrangement of elastic plate 200 with respect to the thermal/viscous boundary layer region 115 such that there is at least some disruption of thermal/viscous boundary layer region 115 sufficient to provide at least some cooling near PCB 110 (e.g., providing at least some cooling for second heat generating component 110_{D}).

In embodiments in which the elastic plate 200 is arranged at a position above the surface of the PCBA 100 that is selected based on the location of thermal/viscous boundary layer region 115, the position determined to be proximate the thermal/viscous boundary layer region 115 may be determined by determining the location of the thermal/viscous boundary layer region 115 with respect to the surface of the PCBA 100 and then using the determined location of thermal/viscous boundary layer region 115 with respect to the surface of the PCBA 100 to determine the position at which the elastic plate 200 is arranged. In one embodiment, the position at which the elastic plate 200 is arranged may be determined using the determined location of thermal/viscous boundary layer region 115 with respect to the PCBA 100 in combination with other information (e.g., information regarding the potential positions on the surface of PCB 110 at which the elastic plate 200 may be mounted (which also may be referred to as available real estate on PCB 110), information indicative of a maximum height above the surface of PCBA 100 at which the elastic plate may be mounted (e.g., due to characteristics of air flow 112, due to the presence of adjacent structure when deployed, and the like, as well as various combinations thereof), information indicative of one or more positions at which it is necessary or desirable to provide disruption of thermal/viscous boundary layer region 115, and the like, as well as various combinations thereof).

In embodiments in which the elastic plate 200 is arranged at a position above the surface of the PCBA 100 that is selected based on the location of thermal/viscous boundary layer region 115, the location of the thermal/viscous boundary layer region 115 with respect to the surface of the PCBA 100 may be determined in any suitable manner. In one embodiment, for example, a prototype of the PCBA 100 for which the elastic plate 200 is to be used may be constructed and analyzed to determine the location of thermal/viscous boundary layer region 115 with respect to the PCBA 100. In one embodiment, for example, the PCBA 100 for which the elastic plate 200 is to be used may be modeled virtually via a computer and the virtual model of the PCBA 100 may be analyzed (e.g., using software configured to provide fluid dynamics analysis and/or any other suitable software) to determine the location of thermal/viscous boundary layer region 115 with respect to the PCBA 100. The location of thermal/viscous boundary layer region 115 with respect to the surface of the PCBA 100 may be determined in any other suitable manner.

In such embodiments, the location of the thermal/viscous boundary layer region 115 with respect to the surface of the PCBA 100 may be defined in any suitable manner. In one embodiment, for example, the location of the thermal/viscous boundary layer region 115 with respect to the surface of the PCBA 100 may be defined in terms of the height of the thermal/viscous boundary layer region 115 with respect to the surface of the PCBA 100 (which may vary over at least some portions of the surface of the PCBA 100, as depicted and described with respect to FIGS. 1 and 2) and a thickness of the thermal/viscous boundary layer region 115 (which also may vary over at least some portions of the surface of the PCBA 100). In one embodiment, for example, the location of the thermal/viscous boundary layer region 115 with respect to the surface of the PCBA 100 may be defined in terms of a curve which represents the top of the thermal/viscous boundary layer region. It is noted that such heights/curves may be represented in any suitable manner (e.g., using discrete points along the surface of PCBA 100, using a continuous points along the surface of PCBA 100, and the like). It is noted that the location of the thermal/viscous boundary layer region 115 with respect to the surface of the PCBA 100 also may be considered to be a profile of thermal/viscous boundary layer region 115 with respect to the surface of the PCBA 100. In such embodiments, further construction and/or modeling may be used to further refine determination of the location of thermal/viscous boundary layer region 115 with respect to the surface of PCBA 100 and, thus, to further refine determination of the position at which the elastic plate 200 is to be arranged with respect to the determined location of the thermal/viscous boundary layer region 115.

The arrangement of the elastic plate 200 at a position above the surface of PCBA 100 may include arranging the elastic plate 200 above a particular location on the surface of PCB 110 and at a particular height above the surface of PCB 110, where the particular location and particular height may depend on one or more factors (e.g., the location of real estate on the surface of PCB 110 that is available for coupling of the elastic plate 200 to the surface of PCB 110, one or more characteristics of the elastic plate 200, one or more characteristics of PCBA 100, the location of the thermal/viscous boundary layer region 115, and the like, as well as various combinations thereof). On the exemplary PCBA 100 of FIG. 2, for example, in a direction (along the surface of the PCB 110 to which the heat generating components 111 are coupled) parallel to incoming air flow 112, the elastic plate 200 is disposed between the first heat generating component 111_{U} and the second heat generating component 111_{D}. On the exemplary PCBA 100 of FIG. 2, for example, in a direction (above and normal to the surface of the PCB 110 to which the heat generating components 111 are coupled), elastic plate 200 is disposed at a height above the surface of the PCB 110 that is adapted to position the elastic plate 200 proximate thermal/viscous boundary layer region 115 so as to enable at least some disruption of the thermal/viscous boundary layer region 115. The elastic plate 200 is configured to flutter in response to the air flow 112 being incident thereon. The fluttering of the elastic plate 200 introduces turbulence in the air, thereby causing mixing of the air near the thermal/viscous boundary layer region 115 and, thus, causing at least a partial disruption of thermal/viscous boundary layer region 115. This increases the effective heat transfer coefficient of components downstream of the elastic plate 200 relative to the direction of air flow 112 (illustratively, the second heat generating component 111_{D}). Although omitted from FIG. 2 for purposes of clarity, it will be appreciated that elastic plate 200 will be cantilevered (e.g., via coupling of the elastic plate to the surface of PCB 110 on which the heat generating components 111 are disposed).

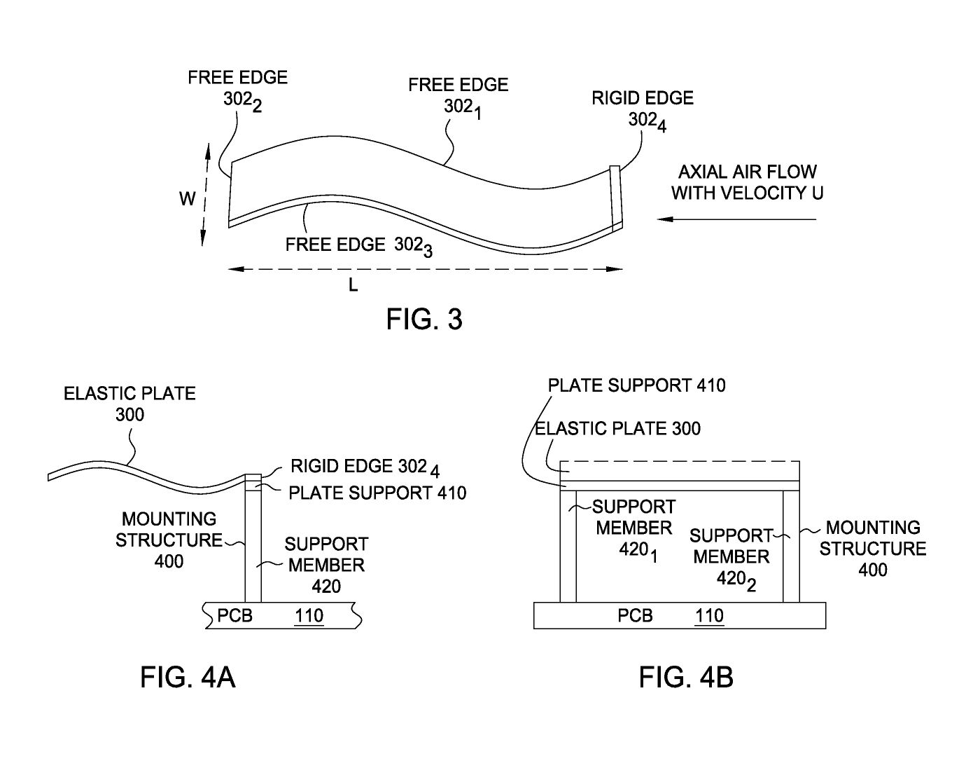

The elastic plate 200 is implemented in a manner suitable to produce fluttering sufficient to disrupt the thermal/viscous boundary layer region 115. An exemplary elastic plate is depicted and described with respect to FIG. 3.

FIG. 3 depicts a view of an exemplary elastic plate configured for use as the elastic plate of FIG. 2.

The elastic plate 300 has properties associated therewith.

The elastic plate 300 has geometric properties associated therewith (e.g., length, width, and thickness).

The elastic plate 300 has material properties associated therewith (e.g., material type, Young's modulus, density, Poisson's ratio, and the like).

The elastic plate 300 has boundary properties associated therewith. The elastic plate 300 includes four edges 302₁-302₄ (collectively, edges 302). The four edges 302 include three edges that are free (illustratively, edges 302₁-302₃) and one edge that is rigid (illustratively, edge 302₄). The rigid edge 302₄ is configured to be a point of attachment enabling cantilevering of the elastic plate 300 with respect to the surface of PCB 110 on which the elastic plate 300 is to be mounted. It is noted that cantilevered mounting of elastic plate 300 implies that (1) three edges 302 of elastic plate 300 are free (illustratively, edges 302₁-302₃) and (2) one edge 302 of elastic plate 300 is mounted/supported such that this edge 302 is neither free to translate in space nor rotate about itself (illustratively, rigid edge 302₄ which functions as a point of attachment of the elastic plate 300 to a mounting structure configured to mount the elastic plate 300 to the surface of PCB 110). An exemplary mounting structure configured to mount elastic plate 300 to PCB 110 is depicted and described with respect to FIG. 4.

The elastic plate 300 is configured to flutter as a result of air flow incident on elastic plate 300 (e.g., the air flow 112 of FIGS. 1 and 2). In general, flutter of elastic plates is determined by: (1) the direction (relative to the plate orientation) and magnitude of the incoming air flow, the geometric properties (e.g., length, width, and thickness) and material properties (e.g., Young's modulus, Poisson's ratio, and the like) of the elastic plate, and the boundary (e.g., support or mounting) conditions of the plate edges of the elastic plate.

The elastic plate 300 will exhibit self-sustained, resonant transverse oscillations when located in a uniform axial flow field of specific velocity (illustratively, in air flow 112 of FIGS. 1 and 2). The resonant transverse oscillations exhibited by the elastic plate 300 will depend on its various properties and the velocity of the air flow. These resonant transverse oscillations exhibited by the elastic plate 300 may be referred to as the aerodynamic flutter modes of the elastic plate 300. The flutter motion of the elastic plate 300 is used to sufficiently disturb the air flow near a thermal/viscous boundary layer region so as to disrupt the thermal/viscous boundary layer region. This results in mixing of relatively high temperature (low viscosity) and low temperature (high viscosity) air regions separated by the thermal/viscous boundary layer region, thereby increasing the effective heat transfer coefficient of components downstream in the direction of the air flow which produces the fluttering of the elastic plate 300.

The various properties of the elastic plate 300 may be selected in any manner suitable to induce flutter, via coupled aero-elastic relationships, sufficient to disrupt thermal/viscous boundary layer region 115, which may depend on various factors related to determination of the flutter of elastic plates and properties of thermal/viscous boundary layer region 115 (e.g., the velocity of the air flow incident on elastic plate 300, the temperature of the air flow incident on elastic plate 300, the direction of the air flow incident on elastic plate 300 relative to orientation of elastic plate 300, properties of the thermal/viscous boundary layer region 115, the size(s)/location(s) of the targeted heat generating components to be cooled, the temperature(s) of the targeted heat generating component(s) 111 to be cooled, the distance between the upstream and downstream heat generating components 111 between which the elastic plate 300 is disposed, the number of elastic plates 300 to be used, the arrangement of elastic plate(s) 300 relative to air flow 112 and heat generating components 111, geometric and material properties of the elastic plate 300, and the like, as well as various combinations thereof).

FIGS. 4A and 4B depict views of an exemplary mounting structure configured to mount the elastic plate of FIG. 3 to the printed circuit board of FIG. 1.

As depicted in FIGS. 4A and 4B, mounting structure 400 is configured to mount elastic plate 200 (e.g., as represented via elastic plate 300 of FIG. 3) to PCB 110.

As further depicted in FIGS. 4A and 4B, the mounting structure 400 includes a plate support 410 and a pair of support members 420₁ and 420₂ (collectively, support members 420). It is noted that plate support 410 and the support members 420 may be implemented as a single component or may be implemented as separate components that are coupled to each other (e.g., via an adhesive, a clip, and/or any other suitable coupling mechanism).

The plate support 410 is configured to support attachment of the rigid edge 302₄ of elastic plate 300. The rigid edge 302₄ of elastic plate 300 may be coupled to plate support 410 in any suitable manner. For example, rigid edge 302₄ may be coupled to plate support 410 on any suitable surface of plate support 410 (e.g., a top surface, a side surface, and the like). For example, rigid edge 302₄ may be coupled to plate support 410 using an adhesive, a mechanical attachment, and the like, as well as various combinations thereof.

The support members 420 are configured to support the plate support 410 in a manner enabling mounting of elastic plate 300 at a specific height above the surface of PCB 110 (illustratively, at a height above the surface of the PCB 110 that enables disruption of the thermal/viscous boundary layer region 115 via flutter of elastic plate 300). The support members 420 each have two ends, each including a first end configured to be coupled to the plate support 410 and a second end configured to be coupled to the surface of PCB 110.

In FIG. 4A, which depicts a view in which the air flow 112 would be incident on the elastic plate 300 in a direction from left to right on the page, a free edge 302 of elastic plate 300 is visible, a portion of rigid edge 302₄ is visible, and a side edge of one of the support members 420 is visible (the other support member is located behind the visible support member 420 and, thus, cannot be seen in this view). In FIG. 4A, it may be seen that elastic plate 300 is mounted on PCB 110 in a cantilevered position such that it is cantilevered with respect to the surface of PCB 110.

In FIG. 4B, which depicts a view in which the air flow 112 would be incident on the elastic plate 300 in a direction normal to the plane of the page, both support members 420 are visible, plate support 410 is visible, and at least a portion of elastic plate 300 is visible (depending on the fluttering of the elastic plate 300 at any given time). It will be appreciated that (a) where the air flow 112 is into the page, the elastic plate 300 would extend behind the page and, similarly, (b) where the air flow is out of the page, the elastic plate 300 would extend in front of the page.

It is noted that, although primarily depicted and described herein as being separate components, in at least one embodiment the elastic plate 300 and mounting structure 400 may be implemented as a single component. In one embodiment, for example, the plate support 410 may be used as the rigid edge 302₄ such that a separate rigid edge 302₄ is not needed. In one embodiment, for example, the rigid edge 302₄ may be mounted directly to the first ends of the support members 420 such that a separate plate support 410 is not needed. Various other configurations are contemplated.

It is noted that the mounting structure 400 is merely one example of a mounting structure which may be used to mount elastic plate 300 to PCB 110. It will be appreciated that, although primarily depicted and described herein with respect to an embodiment of mounting structure 400 that has a specific shape, size, and arrangement of portions/components, the mounting structure 400 may be implemented using various other shapes, sizes, and/or arrangements of portions/components. Thus, more generally, it is noted that, in at least some embodiments, the mounting structure 400 that is used to mount the elastic plate 300 to PCB 110 may be designed to be a low-drag structural support so as to ensure that the air flow 112 is unimpeded (or at least only minimally impeded) by the mounting structure 400. In one embodiment, for example (depicted in FIG. 4), the support members 420 may be designed to be relatively small (e.g., in terms of their width relative to the width of the elastic plate 300). In one embodiment, for example (omitted from FIG. 4 for purposes of clarity), the support members 420 may be designed such that they have an aerodynamic contour conducive to allowing air flow 112 to be unimpeded (e.g., using a teardrop shape in which the narrow side is aligned to face the direction from which the air flow 112 is received, or using any other aerodynamic shape). Various other configurations are contemplated.

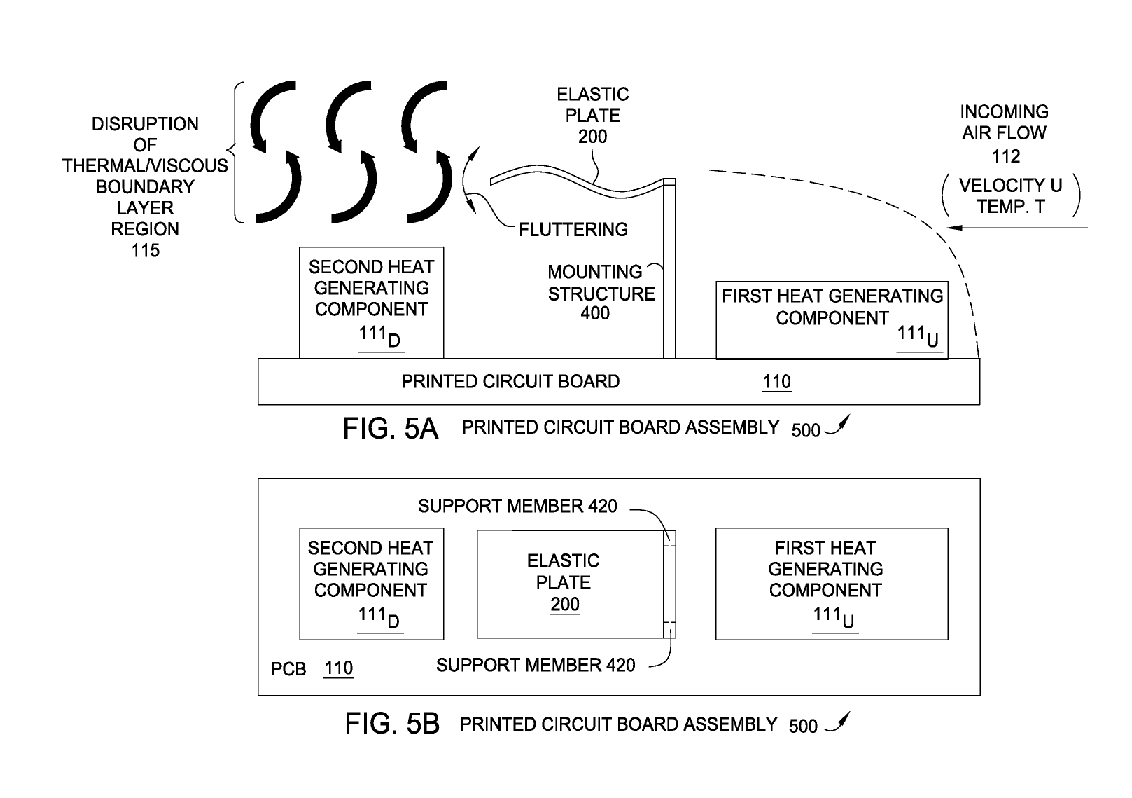

FIGS. 5A and 5B depict side and top views of an exemplary printed circuit board assembly illustrating use of the mounting structure of FIG. 4 to mount the elastic plate of FIG. 2 such that the elastic plate is cantilevered with respect to the printed circuit board of FIG. 1.

As depicted in FIGS. 5A and 5B, the printed circuit board assembly (PCBA) 500 is similar to PCBA 100 of FIG. 2 and illustrates mounting of the elastic plate 200 of FIG. 2 to PCB 110 using the mounting structure 400 of FIG. 4.

As depicted in FIGS. 5A and 5B, elastic plate 200 is mounted in a cantilevered position such that cantilevered elastic plate 200 extends in a direction from the upstream heat generating component 111_{U} toward the downstream heat generating component 111_{D}. The air flow 112 impinges the cantilevered end (leading edge) of cantilevered elastic plate 200, thereby causing fluttering of cantilevered elastic plate 200 in a manner tending to disrupt the thermal/viscous boundary layer region 115.

As depicted in FIGS. 5A and 5B, mounting structure 400 is configured to mount the elastic plate 200 to PCB 110 such that the elastic plate 200 is arranged in a manner tending to disrupt the thermal/viscous boundary layer region 115 when air flow 112 is incident on elastic plate 200. As depicted in FIGS. 5A and 5B, for example, the mounting structure 400 is coupled to the surface of PCB 110 such that elastic plate 200 is located at a particular position relative to the heat generating components 111 (e.g., at a suitable distance from the upstream heat generating component 111_{U} and at a suitable distance from the downstream heat generating component 111_{D}). As depicted in FIG. 5A, for example, the mounting structure 400 is configured such that elastic plate 200 is located at a particular position relative to the top surface of the PCB 110 (e.g., at any suitable height above the surface of PCB 110). It is noted that the positioning of elastic plate 200 in this manner using mounting structure 400 may be determined based on various factors (e.g., the location of the thermal/viscous boundary layer region 115, the location of real estate on the surface of PCB 110 that is available for coupling the mounting structure 400 to the surface of PCB 110, one or more characteristics of elastic plate 200 (e.g., dimensions of elastic plate 200, one or more characteristics of the material used for elastic plate 200, and the like), one or more characteristics of the air flow 112 (e.g., temperature and/or velocity), and the like, as well as various combinations thereof).

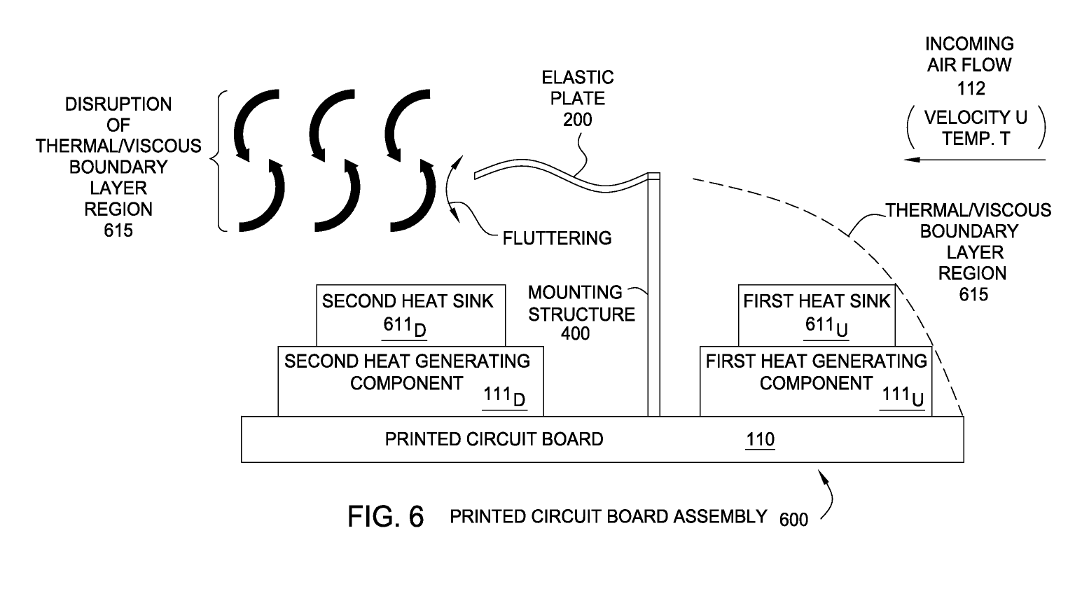

FIG. 6 depicts a side view of the exemplary printed circuit board assembly of FIG. 5 illustrating use of heat sinks on the heat generating components of the printed circuit board assembly of FIG. 5.

As depicted in FIG. 6, printed circuit board assembly (PCBA) 600 is similar to PCBA 500 of FIGS. 5A and 5B, with the difference being inclusion of a pair of heat sinks 611 including a first heat sink 611_{U} disposed on top of the first heat generating component 111_{U} and a second heat sink 611_{D} disposed on top of the second heat generating component 111_{D}. The use of heat sinks 611 to improve cooling of heat generating components 111 will be understood by one skilled in the art.

The incoming air flow 112, in combination with heat generated by heat generating components 111 and heat generated by heat sinks 611, results in formation of the thermal/viscous boundary layer region 115 proximate PCB 110. It is noted that the thermal/viscous profile of thermal/viscous boundary layer region 615 of FIG. 6 is different than the thermal/viscous profile of the thermal/viscous boundary layer region 115 of FIG. 1 at least partially due to the inclusion of additional components on PCB 110.

The elastic plate 200 is positioned above the surface of PCBA 600 such that fluttering of elastic plate 200 tends to disrupt the thermal/viscous boundary layer region 615 when air flow 112 is incident on elastic plate 200. The arrangement of elastic plate 200 in this manner also is depicted and described with respect to FIG. 2 and FIGS. 5A and 5B.

It will be appreciated that the first and second heat sinks 611_{U} and 611_{D} dissipate heat produced by the first and second heat generating components 111_{U} and 111_{D}, respectively, and, thus, may be considered to heat generating components themselves.

Although primarily depicted and described herein with respect to use of a single elastic plate to disrupt a thermal/viscous boundary layer region, it will be appreciated that multiple elastic plates may be arranged in a manner tending to disrupt a thermal/viscous boundary layer region.

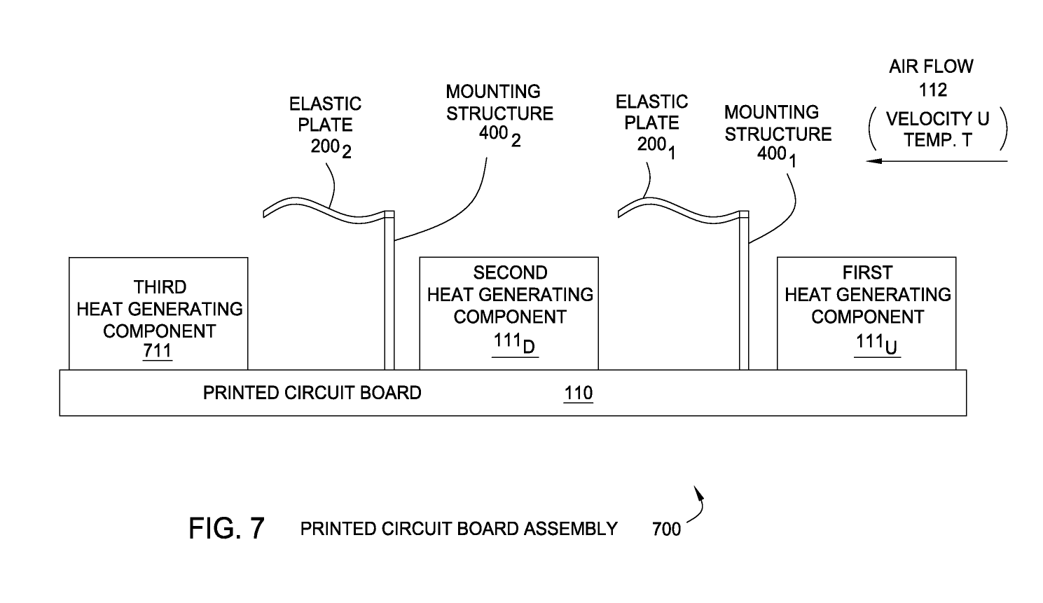

FIG. 7 depicts a side view of an exemplary printed circuit board assembly illustrating mounting of multiple elastic plates to a printed circuit board such that the multiple elastic plates are aligned parallel to the direction of air flow.

As depicted in FIG. 7, the elastic plate 200 of FIG. 2 is labeled as first elastic plate 200₁ and the mounting structure 400 of FIG. 4 is labeled as first mounting structure 400₁. As depicted and described with respect to FIGS. 5A/5B and 6, the mounting structure 400₁ mounts elastic plate assembly 200₁ to PCB 110 between first and second heat generating components 111_{U} and 111_{D}.

As further depicted in FIG. 7, a third heat generating component 711 is mounted to the PCB 110 and a second elastic plate 200₂ is mounted to the PCB 110 in a manner tending to disrupt a thermal/viscous boundary layer region that forms proximate PCB 110. The third heat generating component 711, in the direction of air flow 112, is located downstream of the second heat generating component 111_{D}. The second elastic plate 200₂ is mounted to PCB 110 by a second mounting structure 400₂. The second elastic plate 200₂ is mounted to PCB 110 between the second heat generating component 111_{D} and the third heat generating component 711. The second elastic plate 200₂ is similar to the first elastic plate 200₁. The second mounting structure 400₂ is similar to the first mounting structure 400₁. A combination of the fluttering of the elastic plates 200 disrupts the thermal/viscous boundary layer region that forms proximate PCB 110.

Although primarily depicted and described herein with respect to an embodiment in which multiple elastic plates are mounted on a printed circuit board such that the multiple elastic plates are aligned parallel to the direction of air flow, it will be appreciated that multiple elastic plates may be mounted on a printed circuit board in any suitable arrangement (multiple plates parallel to the direction of air flow, multiple elastic plates normal to the direction of air flow, elastic plates arranged relative to air flow in other ways, and the like, as well as various combinations thereof).

Although primarily depicted and described herein with respect to use of a cantilevered elastic plate to disrupt at least one boundary layer region associated with a specific number and arrangement of heat generating components (illustratively, the first and second heat generating components), it will be appreciated that one or more cantilevered elastic plates may be arranged in a manner tending to disrupt one or more boundary layer regions associated with any suitable number and/or arrangement of heat generating components (e.g., one or more heat generating components arranged in any suitable manner).

Although primarily depicted and described herein with respect to use of a cantilevered elastic plate to improve cooling of an electronic component(s) on a printed circuit board assembly, it will be appreciated that one or more cantilevered elastic plates may be used to improve cooling of one or more other types of components on a printed circuit board assembly.

Although primarily depicted and described herein with respect to use of a cantilevered elastic plate to improve cooling of a component(s) on a specific type of electronic assembly (illustratively, a printed circuit board assembly), it will be appreciated that one or more cantilevered elastic plates may be used to improve cooling of a component(s) on other types of electronic assemblies and devices (e.g., on other types of circuit assemblies, on other types of circuit modules, and the like).

Although primarily depicted and described herein with respect to use of a cantilevered elastic plate to improve cooling of a specific type of component of an assembly or device (illustratively, an electronic component on a printed circuit board assembly), it will be appreciated that one or more cantilevered elastic plates may be used to improve cooling of one or more other types components on an assembly or device (e.g., a mechanical component, an electromechanical component, or any other suitable type of heat generating component).

Although primarily depicted and described herein with respect to use of a cantilevered elastic plate to improve cooling of a component on a specific type of assembly or device (illustratively, an electronic component(s) on a printed circuit board assembly), it will be appreciated that one or more cantilevered elastic plates may be used to improve cooling of one or more components on any other suitable type of assembly or device (e.g., a mechanical assembly, a mechanical device, an electromechanical assembly, an electromechanical device, or any other type of assembly or device which may include a heat generating component).

From the foregoing, it will be appreciated that one or more cantilevered elastic plates may be arranged in a manner tending to disrupt one or more boundary layer regions associated with any suitable types of components of any suitable types of elements. This may include electronic components of electronic assemblies or devices, mechanical components of mechanical assemblies or devices, and the like, as well as various combinations thereof. Accordingly, in one embodiment, an apparatus includes an element having a surface, a heat generating component coupled to the surface of the element, a mounting structure coupled to the surface of the element, and an elastic plate coupled to the mounting structure so as to arrange the elastic plate in a cantilevered position with respect to the surface of the element and above the surface of the element, where the elastic plate is configured to flutter, in response to air flow incident on the elastic plate, in a manner tending to disrupt a boundary layer region. It is noted that the at least one boundary layer region may include at least one of a thermal boundary layer region and a viscous boundary layer region.

Although various embodiments which incorporate the teachings of the present invention have been shown and described in detail herein, those skilled in the art can readily devise many other varied embodiments that still incorporate these teachings.

What is claimed is:

1. An apparatus, comprising:
an element having a surface;
a heat generating component coupled to the surface of the element;
a mounting structure coupled to the surface of the element; and
an elastic plate coupled to the mounting structure so as to arrange the elastic plate in a cantilevered position with respect to the surface of the element and at a position above the surface of the element, the elastic plate configured to flutter, in response to air flow incident on the elastic plate, in a manner tending to disrupt a boundary layer region.

2. The apparatus of claim 1, wherein the position above the surface of the element is selected based on a determined location of the boundary layer region.

3. The apparatus of claim 1 wherein the boundary layer region comprises at least one of a thermal boundary layer region and a viscous boundary layer region.

4. The apparatus of claim 1, wherein the mounting structure comprises a mounting plate and at least one mounting support;
wherein the elastic plate is configured to be coupled to the mounting plate;
wherein each of the at least one mounting support comprises a first end configured to be coupled to the mounting plate and a second end configured to be coupled to the surface of the element to which the heat generating component is coupled.

5. The apparatus of claim 1, wherein the elastic plate comprises a rigid edge and three free edges, wherein the rigid edge is coupled to the mounting structure.

6. The apparatus of claim 1, wherein the elastic plate is configured to flutter in a manner for causing mixing of a first region of air and a second region of air.

7. The apparatus of claim 6, wherein:
for a thermal boundary layer region, the elastic plate is configured to flutter in a manner for causing mixing of a first region of air and a second region of air, the first region of air being closer to the surface of the element than the second region of air and having a higher temperature than the second region of air.

8. The apparatus of claim 6, wherein:
for a viscous boundary layer region, the elastic plate is configured to flutter in a manner for causing mixing of a first region of air and a second region of air, the first region of air being closer to the surface of the element than the second region of air and having a higher viscosity than the second region of air.

9. The apparatus of claim 1, further comprising:
a heat sink coupled to the heat generating component.

10. The apparatus of claim 1, further comprising:
a second heat generating component coupled to the surface of the element;
wherein the mounting structure is coupled to the surface of the element at a position between the heat generating component and the second heat generating component.

11. The apparatus of claim 1, wherein the element is a printed circuit board.

12. The apparatus of claim 1, wherein the apparatus is a printed circuit board assembly.

13. The apparatus of claim 1, wherein the heat generating component is an electronic heat generating component or a mechanical heat generating component.

14. An apparatus, comprising:
a printed circuit board having a surface;
a heat generating component coupled to the surface of the printed circuit board;
a mounting structure coupled to the surface of the printed circuit board; and
an elastic plate coupled to the mounting structure so as to arrange the elastic plate in a cantilevered position with respect to the surface of the printed circuit board and at a position above the surface of the printed circuit board, the elastic plate configured to flutter, in response to air flow incident on the elastic plate, in a manner tending to disrupt a boundary layer region.

15. The apparatus of claim 14, wherein the position above the surface of the element is selected based on a determined location of the boundary layer region.

16. The apparatus of claim 14, wherein the boundary layer region comprises at least one of a thermal boundary layer region and a viscous boundary layer region.

17. The apparatus of claim 14, wherein the mounting structure comprises a mounting plate and at least one mounting support;
wherein the elastic plate is configured to be coupled to the mounting plate;
wherein each of the at least one mounting support comprises a first end configured to be coupled to the mounting plate and a second end configured to be coupled to the surface of the printed circuit board to which the heat generating component is coupled.

18. The apparatus of claim 15, wherein the elastic plate comprises a rigid edge and three free edges, wherein the rigid edge is coupled to the mounting structure.

19. The apparatus of claim 14, wherein the elastic plate is configured to flutter in a manner for causing mixing of a first region of air and a second region of air.

20. An apparatus, comprising:
a mounting structure configured to be coupled to a surface of an element having a heat generating component coupled thereto; and
an elastic plate coupled to the mounting structure so as to arrange the elastic plate in a cantilevered position with respect to the surface of the element and above the surface of the element when the mounting structure is coupled to the surface of the element, the elastic plate configured to flutter, in response to air flow incident on the elastic plate, in a manner tending to disrupt a boundary layer region.
